(19) United States
(12) Patent Application Publication
(10) Pub. No.: US 2008/0060693 A1
(43) Pub. Date: Mar. 13, 2008

(54) Thermoelectric Material Contact

(75) Inventor: Hans-Josef Sterzel, Dannstadt-Schauernheim (DE)

Correspondence Address: OBLON, SPIVAK, MCCLELLAND MAIER & NEUSTADT, P.C., 1940 DUKE STREET, ALEXANDRIA, VA, 22314, US

(73) Assignee: BASF Aktiengesellschaft, Ludwigshafen (DE)

(21) Appl. No.: 11/576,103

(22) PCT Filed: Sep. 24, 2005
(86) PCT No.: PCT/EP05/10364

§ 371 Date: Mar. 27, 2007

(30) Foreign Application Priority Data
Sep. 30, 2004 (DE) 10 2004 048 219.5

(51) Int. Cl. H01L 35/08; H01L 21/00

(52) U.S. Cl. 136/203; 136/200; 438/54; 257/E21.002

(57) ABSTRACT

The invention relates to the thermally stable contacting of semiconductive alloys for use in thermoelectric generators and Peltier arrangements by means of soldering, and to processes for producing thermoelectric modules using a barrier layer composed of borides, nitrides, carbides, phosphides and/or silicides.

The invention relates to the thermally stable contacting of semiconductive alloys for use in thermoelectric generators and Peltier arrangements, and to processes for producing thermoelectric modules using a barrier layer composed of borides, nitrides, carbides, phosphides and/or silicides.

Thermoelectric generators and Peltier arrangements as such have been known for some time. p- and n-doped semiconductors which are heated on one side and cooled on the other side transport electrical charges through an external circuit. These thermoelectric generators allow electrical work to be performed by a load in the circuit. Peltier arrangements reverse the above-described process.

A good review of thermoelectric effects and materials is given, for example, by Cronin B. Vining, ITS Short Course on Thermoelectricity, Nov. 8, 1993 Yokohama, Japan.

At present, thermoelectric generators are used in space probes for generating direct currents, for cathodic corrosion protection of pipelines, for energy supply of light buoys and radio buoys, and also for operating radios and television sets. The advantages of thermoelectric generators lie in their high reliability: for instance, they work irrespective of atmospheric conditions such as atmospheric moisture; there is no fault-prone mass transfer, but rather only charge transfer; the fuel is combusted continuously, and catalytically without a free flame, which releases only small amounts of CO, NOₓ and uncombusted fuel; it is possible to use any fuels from hydrogen through natural gas, gasoline, kerosene, diesel fuel up to biologically obtained fuels such as rapeseed oil methyl ester.

Thermoelectric energy conversion thus fits extremely flexibly into future requirements such as hydrogen economy or energy generation from renewable energies.

A particularly attractive application would be the use for conversion to electrical energy in electrically operated vehicles. In particular, there would be no need for this purpose to undertake any change to the existing network of gas stations.

Thermoelectrically active materials are rated essentially with reference to their efficiency. A characteristic of thermoelectric materials in this regard is what is known as the Z factor (figure of merit):

$$Z = \frac{{S}^{2} \cdot σ}{κ}$$

with the Seebeck coefficient S [μV/degree], the electrical conductivity σ [Ω⁻¹] and the thermal conductivity κ [mW/cm·degree]. Thermoelectric materials are being sought which have a very low thermal conductivity, a very large electrical conductivity and a very large Seebeck coefficient, so that the figure of merit assumes a very high value.

For the conversion of thermal into electrical energy, the efficiency η is:

$$\begin{matrix}η = \frac{{T}_{high} - {T}_{low}}{{T}_{high}} \cdot \frac{M - 1}{M + \frac{{T}_{low}}{{T}_{high}}} \\ where \\ M = [ 1 + \frac{Z}{2} ( {T}_{high} + {T}_{low} ) ] \frac{1}{2}\end{matrix}$$

T_{high}=temperature of the heated side of the semiconductor

T_{low}=temperature of the cooled side of the semiconductor

(see also Mat. Sci. and Eng. B29 (1995) 223).

It is evident from this relationship that especially thermoelectric generators work with a high efficiency when the temperature differential between hot and cooled side is very large. This requires firstly a very high thermal stability of the thermoelectric material, i.e. a very high melting point and as far as possible no phase transitions in the application temperature range, and also particularly high demands on the contacting of the thermoelectric materials.

To prevent losses, the contact material should have very high electrical and thermal conductivity. The mechanical stability should be very high; the contact material must not become detached in the course of operation, it must not flake off.

Also, it must not—and this is critical particularly at high working temperatures—diffuse fully or partly into the semiconductors. In this case, the composition would be changed there and the thermoelectric properties would be degraded in a highly adverse manner.

These problems manifest themselves, for example, in the case of lead telluride as a thermoelectric material (cf. Review of Lead-Telluride Bonding Concepts, Mat. Res. Soc. Symp. Proc., Vol. 234, 1991, pages 167-177):

Virtually every element possible as a solder component reacts with tellurium, as a result of which the sensitive Pb:Te ratio is altered impermissibly. This also relates to dopants, as a result of which, for example, an n-conductive material is convened to a p-conductive material and vice versa.

Solutions which have been discussed include, for example, dimensionally stable, resilient contacting means, but these are both expensive and unreproducible in the sheetlike contact itself.

Weld bonds are also discussed In the case of welding, there is the advantage that no additional material is introduced between contact material and semiconductor. However, the semiconductor is at least briefly partly melted, with the disadvantages that, in the course of cooling, the molten layer recrystallizes with another structure and that the diffusion of contact material into the melt is extremely large.

According to the prior art, preference is thus given to soldering processes with the advantages that the soldering takes place from 100 to 200° C. below the melting point of the semiconductors and that the liquid solder also fills in small fractures and unevenness in an advantageous manner, which results in a high electrical and thermal conductivity.

Prior art solders are typically alloys which comprise bismuth, antimony, tin, lead, copper and/or silver. The melting points are typically below 400° C.

No solder bonds are known which are said to be diffusion-resistant above 400° C. On the contrary, a boundary condition for a good solder bond is that at least one alloy component of the solder diffuses into the materials to be bonded.

It can thus be stated from the outset that there are no high temperature-stable, diffusion-resistant solder bonds.

Apparently for this reason, it has already been proposed to introduce a barrier layer between the contact material and the semiconductors (JP 2000-043637). Barrier layers composed of nickel phosphides, nickel borides and an additional layer of gold are discussed.

Nevertheless, barrier layers for bonding to the contact material also require an additional solder which has the task of bonding the barrier layer firmly to the contact material.

It is an object of the invention to provide a suitable combination of solder and barrier material, which ensures both secure mechanical bonding and constant, good long-term properties of the thermoelectric material even at elevated temperatures of above 400° C.

The object is achieved by providing the thermoelectrically semiconductive material with a barrier layer composed of borides, nitrides, carbides, phosphides and/or silicides, and bonding this layer to the actual contact material by soldering.

The invention thus provides thermoelectric modules, wherein the thermoelectrically semiconductive material has been provided with a barrier layer composed of borides, nitrides, carbides, phosphides and/or silicides, and this layer has been bonded to the actual contact material by soldering.

The invention further provides a process for producing such thermoelectric modules, and thermoelectric generators or Peltier arrangements which comprise such thermoelectric modules.

The invention can be applied with all known thermoelectrically semiconductive materials. Suitable materials are, for example, described in Mat. Sci, and Eng, B29 (1995) 228. It is particularly advantageous in the case of semiconductors based on tellurides. These are generally known tellurides, such as lead telluride, and modifications thereof in which lead has been replaced by elements such as tin, and tellurium partly by selenium.

It is also possible to use substituted semiconductor materials for example, tellurides in which the positively polarized atoms of the crystal lattice of the telluride have been substituted partially by silicon and/or germanium. A typical composition of a material in this sense is, for example, PbTe.(Si₂Te₃)_{0.01}. In this case, “partial” refers to a degree of substitution of preferably from 0.002 to 0.05 mol, more preferably from 0.003 to 0.02 mol, in particular from 0.008 to 0.013 mol, per mole of telluride formula unit. Such substituted tellurides, their preparation and properties are described, for example, in the DE patent application No. 102004025066.9 which was yet to be published at the priority date of the present application.

The unsubstituted or substituted semiconductor materials described may be used without further doping. However, they may also comprise further compounds, in particular other customarily used dopants.

The tellurides in particular may additionally be doped. When the tellurides are doped, the proportion of doping elements is preferably up to 0.1 atom % (from 10¹⁸ to 10¹⁹ atoms per cubic centimeter of semiconductor material), more preferably up to 0.05 atom %, in particular up to 0.01 atom %.

Doping is effected with elements which bring about an electron excess or deficiency in the crystal lattice. Suitable doping metals for p-semiconductors are, for example, the following elements: lithium, sodium, potassium, magnesium, calcium, strontium, barium and aluminum. Suitable doping metals for n-semiconductors are the elements chlorine, bromine and iodine,

It is possible by doping to convert the conduction type to the counterpart.

The thermoelectrically semiconductive materials used in accordance with the invention have been provided with a barrier layer. The barrier layer consists of compounds having very good electrical conductivity and a rigid crystal lattice, which prevents diffusion through these layers.

According to the invention, the barrier layer consists of borides, nitrides, carbides, phosphides and/or silicides.

Specific examples of useful compound classes for this purpose are the following:

nitrides such as TiN, TaN, CrN, ZrN, AlTiN;

carbides such as TiC, TiCN, TaC, MoC, WC, VC, Cr₃C₂;

phosphides such as Ni₂P, Ni₅P₂;

borides such as TiB₂, ZrB₂, HfB₂, VB₂, NbB₂, TaB₂, CrB₂, Mo₂B₅, W₂B₅, FeB, CoB, NiB, Ni₂B, Ni₃B;

or

silicides such as VSi₂, NbSi₂, TaSi₂, TiSi₂, ZrSi₂, MoSi₂, WSi₂.

Also suitable are mixtures of these compounds with one another.

Advantageously, Ni₂B, Ni₃B, Ni₂P and/or Ni₅P₂ or else other nickel phosphides and borides are used. The very strong binding of nickel to phosphorus or boron virtually completely nullifies the diffusion capability of nickel. Boron and phosphorus additionally do not form any tellurides.

Before or after they are divided to the use dimensions, the semiconductors are provided on both sides with the above-described barrier layer. This may be applied by various processes, for example by sputtering starting from a target of the same composition, as described, for example, in J. Appl. Phys., Vol. 79 No. 2, 1109-1115, 1996, or by M. E. Thomas et al., VLSI Multilevel Interconnection Conference Proceedings, Fifth Int. IEEE, 1988, or generated by physical vapor deposition, as described, for example, in D. S. Dickerby, A. Matthews, Advanced Surface Coatings, Blackie, Glasgow, 1991 and Handbook of Physical Vapor Deposition (PVD) Processing, ISBN 0-8155-1422-0.

The barrier layer is bonded to the contact material by soldering.

Advantageously, the solder material used comprises alloys of nickel, especially alloys of nickel with Mg, Sn or Zn.

Particularly good results are exhibited by combinations with the following alloys as solder material:

Mg₂Ni (melting point approx. 760° C.),

Ni₃SN₄ (melting point approx. 794° C.),

Zn/Ni with from 70 to 95% by weight of Zn (for example, in the case of 90% by weight of Zn, melting point approx. 800° C.).

To increase the melting point, the Ni content is increased and to lower it, conversely, the Ni content is lowered.

Owing to their Ni content, the solder materials enter into a good bond with the barrier layers.

The solder material serves to bond the barrier layers to the actual contact sheets. The application of the solder material may be effected in any suitable manner. It is advantageous to apply the solder material to the actual contact sheet by thermal spraying.

For the soldering, in this case, the contact sites are either brought to the necessary temperature thermally by external means or resistance soldering is carried out, in which the unsoldered contacts are brought to the solder temperature by current flow. Resistance to soldering has the advantage of self-regulation: as long as the solder site is not soldered over the full surface, it has increased electrical resistance, and there is a greater drop in voltage and a greater drop in power at constant current. This makes the solder site hotter. When the solder has a flat profile, the resistance and thus the temperature fall.

However, it is also possible to use other prior art processes for applying the solder material and for the soldering. A good overview of currently employed solder processes is given by the commercial publication “Lötverfahren” [“Solder processes”] from Braze Tec GmbH (www.BrazeTec.de).

The solder temperature has to be adjusted to the particular materials and is advantageously from 10 to 100° C. above the liquidus temperature of the solder. The solder times have to be adjusted to the particular conditions of heat capacity and heat conductivity.

The process according to the invention has the advantage that the contact material does not diffuse into the semiconductors even at high temperatures, so that the composition of the semiconductor material is not altered and the thermoelectric properties are thus not adversely affected. The use of the barrier layers described has the result that the inventive thermoelectric modules have a greater use temperature stability in comparison to those having conventional barrier layers.

Thermoelectric generators or Peltier arrangements with the thermoelectric modules described are particularly suitable for use at elevated temperatures of greater than 300° C.

1. A thermoelectric module, wherein the thermoelectrically semiconductive material has been provided with a barrier layer composed of borides, nitrides and/or silicides, and this layer has been bonded to the actual contact material by soldering, the solder material comprising alloys of nickel, wherein said borides are selected from the group consisting of TiB₂, ZrB₂, HfB₂, VB₂, NbB₂, TaB₂, CrB₂, Mo₂B₅, W₂B₅, FeB and CoB.

2. The thermoelectric module according to claim 1, wherein the solder material comprises alloys of nickel with Mg, Sn or Zn.

3. A process for producing thermoelectric modules, wherein a barrier layer composed of borides, nitrides and/or silicides is applied to the thermoelectrically semiconductive material and this layer is subsequently bonded to the actual contact material by soldering, the solder material used comprising alloys of nickel, wherein said borides are selected from the group consisting of TiB₂, ZrB₂, HfB₂, VB₂, NbB₂, TaB₂, CrB₂, Mo₂B₅, W₂B₅, FeB and CoB.

4. The process according to claim 3, wherein the solder material is applied to the contact sheet by thermal spraying.

5. The process according to claim 3, wherein the barrier layer is bonded to the contact material by resistance soldering.

6. A thermoelectric generator or Peltier arrangement comprising thermoelectric modules according to claim 1.

7. The process according to claim 4, wherein the barrier layer is bonded to the contact material by resistance soldering.

8. A thermoelectric generator or Peltier arrangement comprising thermoelectric modules according to claim 2.
